(19) United States
(12) Patent Application Publication
(10) Pub. No.: US 2015/0194366 A1
(43) Pub. Date: Jul. 9, 2015

(54) HEAT TRANSFER STRUCTURE AND MANUFACTURING METHOD THEREOF

(71) Applicant: Ntrium Inc., Suwon-si (KR)

(72) Inventor: Se Young JEONG, Suwon-si (KR)

(21) Appl. No.: 14/591,363

(22) Filed: Jan. 7, 2015

(30) Foreign Application Priority Data
Jan. 7, 2014 (KR) 10-2014-0001586
Jan. 7, 2014 (KR) 10-2014-0001587

(51) Int. Cl. H01L 23/373; H01L 21/48

(52) U.S. Cl. CPC H01L 23/3736; H01L 21/4882

(57) ABSTRACT

The present invention provides a heat transfer structure which includes a first object, a second object and a thermal transfer adhesive material which is placed between the first object and the second object so as to be in contact with at least one of the first object or the second object. The heat transfer adhesive material includes a resin and at least one thermal conductive material, and the at least one thermal conductive material is distributed by being dispersed in the resin and forms surface contact with at least one of the first object or the second object.

### CROSS-REFERENCE TO RELATED APPLICATIONS

This application is based on and claims priority to Korean Patent Application No. 10-2014-0001586, filed on Jan. 7, 2014 and Korean Patent Application No. 10-2014-0001587, filed on Jan. 7, 2014, the disclosures of which are incorporated herein in its entirety by reference.

### FIELD OF THE INVENTION

The present invention relates to a heat transfer structure and manufacturing method thereof, and in particular, relates to a heat transfer structure and method of manufacturing the same capable of more effectively dissipating heat generated by internal components such as a semiconductor chip by placing a plurality of thermal conductive material which are uniform in size in one layer between the semiconductor chip and a heat dissipation component and having the plurality of thermal conductive material to be in surface contact with the semiconductor chip and the heat dissipation component.

### BACKGROUND OF THE INVENTION

In general, a heat dissipation component such as a heat sink, a heat slug, a cooling device, a metal case or the like is attached to a heat generating portion of a high exothermic semiconductor chip and the heat in the heat generating portion is dissipated through the heat dissipation component. In this regard, a material to be used for attaching the heat dissipation component to the chip is referred as TIM (Thermal Interface Material).

A conventional TIM material may be formed by dispersing and distributing thermal conductive materials which are non-metallic materials and have a high thermal conductivity in a material such as a resin having a strong adhesive strength. Such a thermal conductive material may be a particle such as an alumina, an aluminum nitride or a boron nitride having an atypical irregular shape, which are extremely hard such that they cannot be compressed by a pressure.

However, such a conventional TIM material may be subject to a thermal bottleneck, because the TIM material has a relatively lower thermal conductivity than that of a heat sink.

One of the reasons why the thermal conductivity of the conventional TIM material is low may be an interface resistance of the thermal conductive material. In this regard, referring to FIG. 1 which shows a cross-sectional view of a conventional TIM material 50, heat generated in the semiconductor chip 20 may pass through a plurality of thermal conductive materials 51 being connected in series each other and may be transferred to a heat dissipation component 30. At this time, due to an interface resistance between each of the plurality of thermal conductive materials 51 through which the heat passes, the thermal conductivity of the conventional TIM material 50 may be low.

Further, as shown in FIG. 1, thermal conductive materials 52 and 53 may be distributed not to be in contact with the semiconductor chip 20 or the heat dissipation component 30, which may also cause the thermal conductivity of the conventional TIM material 50 to be low.

Another reason why the thermal conductivity of the conventional TIM material is low may be that thermal conductive materials 51 through 53 are formed to be in point contacts with the semiconductor chip 20 and/or the heat dissipation component 30 as shown in FIG. 1. In case the heat generated in the semiconductor chip 20 is transferred via the point contacts to the heat dissipation component 30, the thermal conductivity becomes low due to the small area made by the point contacts (e.g., point contact between the semiconductor chip 20 and the thermal conductive material 51 and point contact between two adjacent thermal conductive materials, etc.)

In order to solve the thermal bottleneck, therefore, it is required to minimize the interface resistance between the thermal conductive materials through which heat passes and at the same time to increase a contact area between the thermal conductive material and the semiconductor chip and/or the heat dissipation component.

### SUMMARY OF THE INVENTION

In view of the above, an embodiment of the present invention provides a heat transfer structure having a configuration of reducing the interface resistance of the thermal conductive material through which a generated heat passes, and a manufacturing method thereof.

Further, an embodiment of the present invention provides a heat transfer structure having a configuration for the thermal conductive material to be in contact with the semiconductor chip and/or the heat dissipation component over the area larger than the area of the point contact, and a manufacturing method thereof.

In accordance with an embodiment of the present invention, there is provided a heat transfer structure that includes a first object, a second object and a thermal transfer adhesive material which is placed between the first object and the second object so as to be in contact with the first object or the second object, and the heat transfer adhesive material includes a resin and at least one thermal conductive material which is distributed by being dispersed in the resin and has surface forming surface contact with at least one of the first object or the second object.

Further, the at least one thermal conductive material is uniform in size.

Further, a thermal conductivity of the thermal conductive material is in the range of 1 to 5000 W/mK.

Further, the surface is formed by melting the thermal conductive material.

Further, a melting temperature of the thermal conductive material is lower than a thermal decomposing temperature of the resin.

Further, the melting temperature of the thermal conductive material is in the range of 20° C. to 450° C.

Further, the thermal conductive material is at least any one or combination of Sn, Ag, Bi, Pb, Cd, Zn, SnAg, SnBi, InSn, SnCu, SnPb and SnCuAg.

Further, the surface is formed by pressing the thermal conductive material by a pressure applied to the first object and the second object.

Further, the thermal conductive material is comprised of a metal or a carbon containing material.

Further, the thermal conductive material includes a core member with elasticity placed inside thereof.

Another embodiment of the present invention provides a method of manufacturing a heat transfer structure that includes: placing a heat transfer adhesive material between a first object and a second object, wherein the heat transfer adhesive material including a resin and at least one thermal conductive material which is distributed by being dispersed in the resin; applying a pressure to the first object and the second object so as for the thermal conductive material to be in contact with the first object and/or the second object; forming a surface, by melting the thermal conductive material, in a portion where the thermal conductive material is in contact with the first object and/or the second object such that the thermal conductive material is in surface contact with at least one of the first object or the second object; and curing the resin.

Further, a melting temperature of the thermal conductive material is lower than a thermal decomposing temperature of the resin.

Further, the melting temperature of the thermal conductive material is in the range of 20° C. to 450° C.

Further, the thermal conductive material is at least any one or combination of Sn, Ag, Bi, Pb, Cd, Zn, SnAg, SnBi, InSn, SnCu, SnPb and SnCuAg.

Another embodiment of the present invention provides a manufacturing method of a heat transfer structure that includes: placing a heat transfer adhesive material between a first object and a second object, wherein the heat transfer adhesive material including a resin and at least one thermal conductive material which is distributed by being dispersed in the resin; applying a pressure to the first object and the second object so as for the thermal conductive material to be squeezed such that the thermal conductive material is in surface contact with at least one of the first object or the second object; and curing the resin.

Further, the thermal conductive material is comprised of a metal or a carbon containing material.

Further, the thermal conductive material includes a core member with elasticity placed inside thereof.

Further, the at least one thermal conductive material is uniform in size.

Further, a thermal conductivity of the thermal material is in the range of 1 to 5000 W/mK.

According to an embodiment of the present invention, thermal conductive materials of which each size is uniform are placed in one layer between the semiconductor chip and the heat dissipation component in order to form a direct thermal path from the semiconductor chip to the heat dissipation component via the thermal conductive material contacting the semiconductor chip and/or the heat dissipation component, resulting in eliminating or minimizing the interface resistance between the thermal conductive materials, thereby increasing the thermal conductivity of the TIM material. Also, by applying heat so as for the thermal conductive material to be melted or applying a pressure so as for the thermal conductive material to be pressed, the thermal conductive material can be formed to be in surface contact with the semiconductor chip and/or the heat dissipation component, thereby increasing the thermal conductivity of the TIM material and accordingly solving the thermal bottleneck.

### BRIEF DESCRIPTION OF THE DRAWINGS

The above and other objects and features of the present invention will become apparent from the following description of the embodiments given in conjunction with the accompanying drawings, in which:

FIG. 1 is a cross-sectional view of the conventional TIM material;

FIG. 2 is a cross-sectional view of the heat transfer structure in accordance with a first embodiment of the present invention;

FIG. 3 is a flow diagram illustrating a manufacturing method of the heat transfer structure in accordance with a first embodiment of the present invention;

FIG. 4 is a cross-sectional view of the heat transfer structure in accordance with a second embodiment of the present invention;

FIG. 5 is a flow diagram illustrating a manufacturing method of the heat transfer structure in accordance with a second embodiment of the present invention;

FIG. 6 is a cross-sectional view of the heat transfer structure in accordance with a third embodiment of the present invention; and

FIG. 7 is a diagram illustrating an exemplary thermal conductivity of the heat transfer structure 300 in accordance with the third embodiment of the present invention.

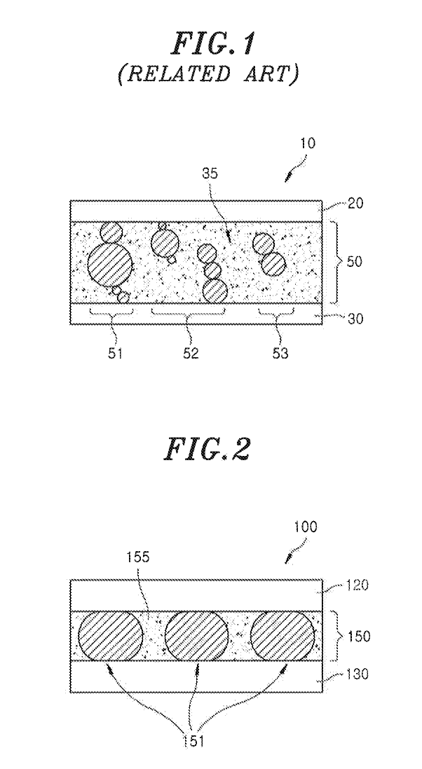

### DETAILED DESCRIPTION OF THE EMBODIMENTS

Hereinafter, exemplary embodiments of the present invention will be described in detail with reference to the accompanying drawings. It should be understood that the present invention is not intended to be limited to those embodiments, but intended to describe the embodiments in detail so as for a person having an ordinary skill in the art to easily carry out them.

FIG. 2 is a cross-sectional view of the heat transfer structure in accordance with a first embodiment of the present invention.

Referring to FIG. 2, a heat transfer structure 100 in accordance with the first embodiment of the present invention may include a first object 120, a second object 130 and a heat transfer adhesive material 150 which is placed between the first object 120 and the second object 130 so as to be contacted to the first object 120 and/or the second object 130. However, the heat transfer structure 100 of the FIG. 2 is merely one of the embodiments of the present invention, and thus the present invention is not limited to the embodiment described in FIG. 2.

The first object 120 may be a component, for example, a semiconductor device such as CPU or RAM which generates heat, but is not limited thereto.

The second object 130 may be a component which receives the heat generated in the first object 120 and emits the heat to the outside. Such a component may be a heat sink, a heat slug, a cooling device, a metal case or the like, but is not limited thereto.

The heat transfer adhesive material 150 may be a material which, while bonding the first object 120 and the second object 130, may transfer the heat generated in the first object 120 to the second object 130. The heat transfer adhesive material 150 may include a resin 155 and at least one thermal conductive material 151 and may further include other auxiliary substances or additives in addition to the materials above mentioned.

The resin 155 may be a material which can bond the first object 120 and the second object 130. Such a material may be a thermosetting resin, an adhesive resin, a silicon resin or an epoxy resin or the like, but is not limited thereto and may further include other materials in addition to the materials above mentioned.

The thermal conductive material 151 which may have a ball type shape may be a material which transfers the heat generated in the first object 120 to the second object 130. The thermal conductivity of the thermal conductive material 151 may be in the range of 1 to 5000 W/mK, but is not limited to this value.

As shown in FIG. 2, the ball-shaped thermal conductive material 151 may be distributed in one layer by being dispersed in the resin between the first object 120 and the second object 130 such that the one layer of a plurality of the thermal conductive materials 151 contact to the first object 120 as well as the second object 130.

In addition, the at least one thermal conductive material 151 may be uniform in size.

Further, the thermal conductive material 151 may include a surface being in contact with at least one of the first object 120 or the second object 130. With this surface, the thermal conductive material 151 may form surface contact with at least one of the first object 120 or the second object 130.

Here, the thermal conductive material 151 may be a material which can be melted by heat. The above described surface contact may be also formed by a thermal melting.

In this regard, a melting temperature of the thermal conductive material 151 may be between 20° C. and 450° C., but is not limited to this value. However, the melting temperature may be lower than a thermal decomposing temperature of the resin 155. Here, the thermal decomposing temperature of the resin means a temperature where adhesion of the resin 155 is lost.

Meanwhile, the thermal conductive material 151 may be made of one material, or an alloy composing of several elements, or a material having different materials in its core and shell (outer surface). For example, the thermal conductive material 151 may include at least any one of Sn, Ag, Bi, Pb, Cd, Zn, SnAg, SnBi, InSn, SnCu and SnCuAg, but is not limited thereto.

In the heat transfer structure 100 in accordance with the first embodiment of the present invention, the thermal conductive material 151 can be distributed in one layer by being dispersed in the resin between the first object 120 and the second object 130. Therefore, heat generated in the first object 120 can be transferred to the second object 130 by passing through the thermal conductive material 151 composing of only one layer. Hereinafter, the configuration of the heat transfer structure 100 including the thermal conductive material 151 composing of only one layer is referred as a direct thermal path.

In the heat transfer structure 100 having the configuration of direct thermal path in accordance with the first embodiment of the present invention, the heat generated in the first object 120 passes through the thermal conductive material 151 composing of only one layer and is transferred to the second object 130. In this case, an interfacial resistance on the path through which the heat passes may be less than the interfacial resistance when the heat passes through a plurality of thermal conductive materials which are connected in series each other. Therefore, according to the first embodiment of the present invention, it is possible to obtain a higher thermal conductivity than that of the conventional TIM material.

In addition, since the at least one thermal conductive material 151 is uniform in size, in case where any one of the thermal conductive material 151 is contacted with the first object 120 and the second object 130, the remaining thermal conductive material 151 may be also contacted with the first object 120 and the second object 130. In other words, all the thermal conductive material 151 composing of only one layer may be contacted with the first object 120 and the second object 130 such that the one layer of a plurality of the thermal conductive material 151 contact the first object 120 and the second object 130. Accordingly, the heat may be transferred directly from the first object 120 to the second object 130 via the one layer of the plurality of the thermal conductive material 151, without the interface resistance between the thermal conductive materials 151. Therefore, according to the first embodiment of the present invention, it is possible to obtain a higher thermal conductivity than that of the conventional TIM material.

Further, the thermal conductive material 151 forms surface contact with at least one of the first object 120 or the second object 130 to secure a large area through which the heat is transferred, and thus it is possible to obtain a higher thermal conductivity compared to the conventional TIM material having a point contact.

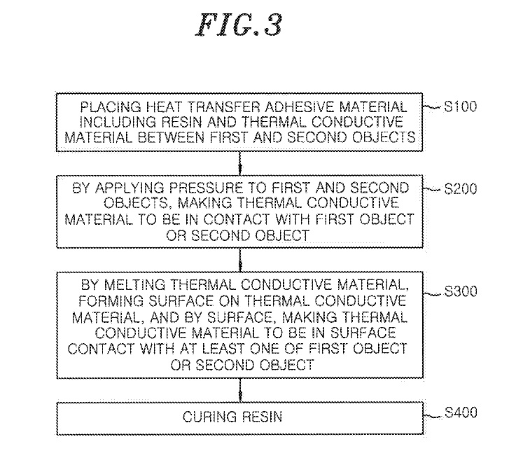

FIG. 3 is a flow chart illustrating a manufacturing method of the heat transfer structure in accordance with the first embodiment of the present invention.

Referring to FIG. 3 and together with FIG. 2, in the manufacturing method of the heat transfer structures 100 in accordance with the first embodiment of the present invention, a process may be carried out that the heat transfer adhesive material 150 is placed between the first object 120 and the second object 130. At this time, at block S100, the heat transfer adhesive material 151 may include the resin 155 and at least one thermal conductive material 151 which is distributed by being dispersed in the resin 155. Here, the heat transfer adhesive material 150 may be dispensed the second object 130, for example by a nozzle discharge system, but is not limited thereto.

Meanwhile, the at least one thermal conductive material 151 which has a ball-type shape may be distributed in one layer by being dispersed between the first object 120 and the second object 130. At this time, the at least one thermal conductive material 151 may be uniform in size.

Next, at block S200, a process may be carried out that the thermal conductive material 151 is contacted with the first object 120 and/or the second object 130 by a pressure to be applied to the first object 120 and the second object 130 such that the ball-shaped thermal conductive material 151 may contact the first object 120 as well as the second object 130, with the thickness of the heat transfer adhesive material being substantially equal to the size of the thermal conductive material 151. At this time, the contact may be, for example a point contact. Also, the thermal conductive materials 151 are uniform in size, as described above. So, in case that any one of the thermal conductive materials 151 is contacted with the first object 120 and the second object 130, the remaining thermal conductive materials 151 can be contacted with the first object 120 and the second object 130 as well.

Next, at block S300, when heat is applied to the thermal conductive material 151, the contact area between the thermal conductive material 151 and the first object 120 or between the thermal conductive material 151 and the second object 130 may be increased due to a partial melting of the outer surface of the thermal conductive material 151. Thereafter, at block S300, a process may be carried out that the thermal conductive material 151 forms surface contact with at least one of the first object 120 or the second object 130.

Here, the melting temperature of the thermal conductive material 151 may be between 20° C. and 450° C., but is not limited to this value and may be lower than a thermal decomposing temperature of the resin 155.

Thereafter, at block S400, a process may be carried out that the resin 155 is cured by applying heat or an UV light. The curing may be carried out, for example, while a pressure is applied to the first object 120 and the second object 130.

In the manufacturing method of the heat transfer structure 100 in accordance with the first embodiment of the present invention, the thermal conductive material 151 forms surface contact with the first object 120 and/or the second object 130 by partially melting of the outer surface of the thermal conductive material 151 caused by heat. Therefore, according to the first embodiment of the present invention, it is possible to obtain a higher thermal conductivity compared to the conventional TIM material having a point contact.

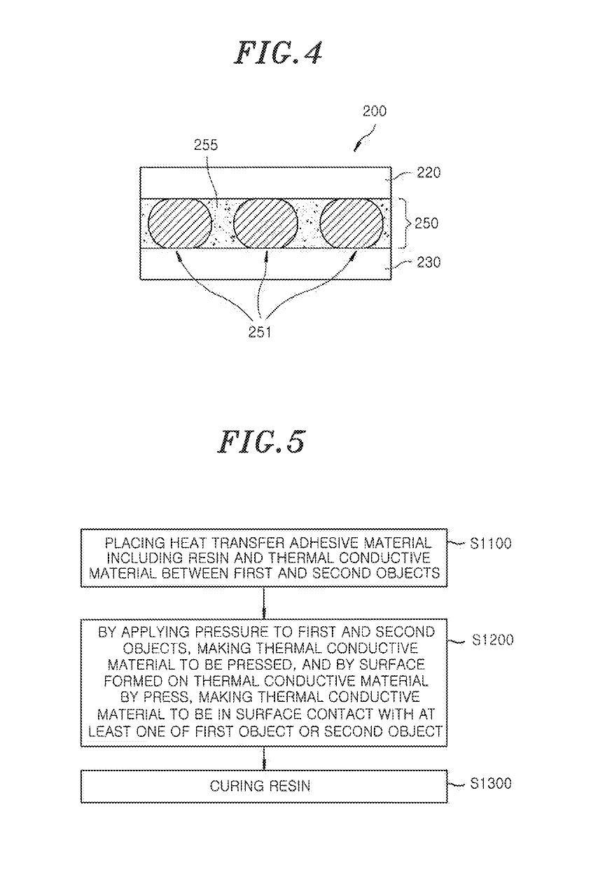

Hereinafter, a heat transfer structure and manufacturing method thereof in accordance with the second embodiment of the present invention will be described with reference to FIGS. 4 and 5. However, there is a difference between the second embodiment and the first embodiment in that, in the second embodiment, the process that the thermal conductive material 151 may form surface contact with at least one of the first object 120 or the second object 130 may be different from that of the first embodiment. The second embodiment will be described on the basis of those differences and will be omitted in describing the same features.

FIG. 4 is a cross-sectional view of the heat transfer structure in accordance with the second embodiment of the present invention.

Referring to FIG. 4, a heat transfer structure 200 in accordance with the second embodiment of the present invention may include a first object 220, a second object 230 and a thermal transfer adhesive material 250 which is placed between the first object 220 and the second object 230 so as for the thermal transfer adhesive material 250 to be contacted with the first object 220 and/or the second object 230.

The first object 220 and the second object 230 are the same as the case of the first embodiment, and thus description thereof will be omitted. Also, the function and the configuration of the thermal transfer adhesive material 250 and a resin 255 are the same as the case of the first embodiment, and thus description thereof will be omitted.

Further, other features of the second embodiment including a thermal conductivity of the thermal conductive material 251, one layer formed by a plurality of the thermal conductive material 251, the uniform size of the thermal conductive material 251, and the surface contact of the thermal conductive material 251 with at least one of the first object 220 or the second object 230 are identical to those of the first embodiment, and thus description thereof will be omitted.

However, in the heat transfer structure 200 in accordance with the second embodiment, the surface contact of the thermal conductive material 251 with at least one of the first object 220 or the second object 230 may be formed by a pressure, differently from the case of the first embodiment.

In other words, the thermal conductive material 251 may be pressed by a pressure which is applied to the first object 220 and the second object 230. As a result, the shape of the thermal conductive material 251 (e.g., ball-shaped) may be deformed to form surface contact to the first object 220 and/or the second object 230. In other words, contact portion between the thermal conductive material 251 and the first object 220 and/or the second object 230 may be increased from a point to an area.

Here, the thermal conductive material 251 may be a material having elasticity, which can be deformed by a pressure. For example, the thermal conductive material 251 may be a metal or a carbon containing material, but is not limited thereto.

According to the second embodiment in accordance with the present invention in which the heat transfer structure 200 has a configuration of a direct thermal path, the at least one thermal conductive material 251 is substantially uniform in size, and the thermal conductive material 251 forms surface contact with at least one of the first object 220 and/or the second object 230. Therefore, it is possible to obtain a higher thermal conductivity than that of the conventional TIM material having only a point contact.

FIG. 5 is a flow diagram illustrating a manufacturing method of the heat transfer structure in accordance with the second embodiment of the present invention.

Referring to FIG. 5 together with FIG. 4, in manufacturing the heat transfer structure 200 in accordance with the second embodiment of the present invention, at block S1100, a process may be carried out that the heat transfer adhesive material 250 including the resin 255 and at least one thermal conductive material 251 which is distributed in one layer by being dispersed in the resin 255 is placed between the first object 220 and the second object 230. As described above, the heat transfer adhesive material 250 may be dispensed between the first object 220 and second object 230, for example, by a nozzle discharge system, and the direct thermal path may be formed from the first object 220 to the second object 230 via one layer of a plurality of the thermal conductive materials 251. Accordingly, description thereof will be omitted.

Next, at block S1200, a process may be carried out that the thermal conductive material 251 is pressed by a pressure which is applied to the first object 220 and the second object 230, and by such pressure, the plurality of the thermal conductive material 251 may be deformed or squeezed to form surface contact with at least one of the first object 220 or the second object 230. At this time, since at least one thermal conductive material 251 is uniform in size, when any particle of the thermal conductive material 251 forms surface contact with the first object 220 and the second object 230, the remaining particle can be also in surface contact with the first object 220 and the second object 230.

Next, at block S1300, a process may be carried out that the resin 255 is cured by heat or a UV light. The curing may be carried out for example, while the first object 220 and the second object 230 are pressed by a pressure such that the surface contact made by the deformation can be maintained even after the pressure is no longer applied.

In the manufacturing method of the heat transfer structure 200 in accordance with the second embodiment of the present invention as described above, since the thermal conductive material 251 can be in surface contact with the first object and/or the second object 230 by a pressing, it is possible to obtain a higher thermal conductivity than that of the conventional TIM material having a point contact.

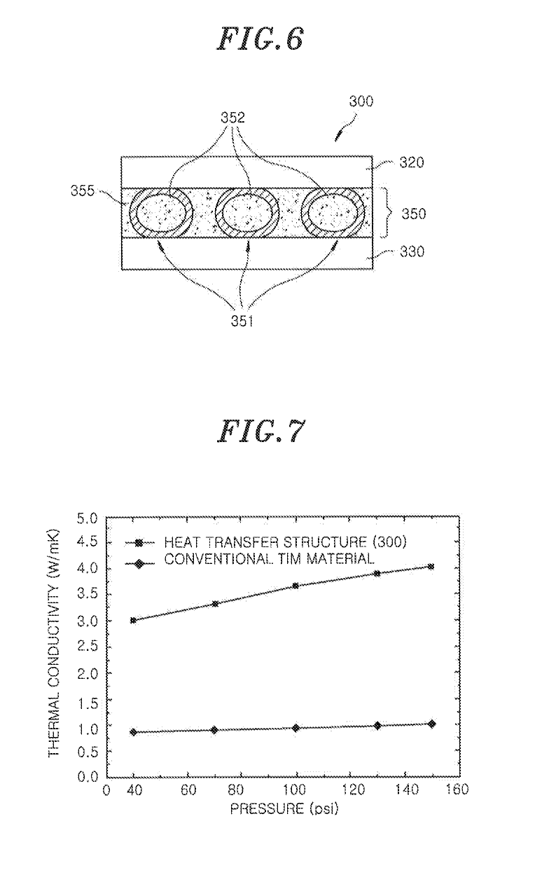

FIG. 6 is a cross-sectional view of the heat transfer structure in accordance with a third embodiment of the present invention. The heat transfer structure in accordance with the third embodiment is identical to that of the second embodiment in terms of configuration and manufacturing method except for the structure of the thermal conductive material 251. Accordingly, the description will be focused on such difference, and the description of the manufacturing method will be omitted.

Referring to FIG. 6, a heat transfer structure 300 in accordance with the third embodiment of the present invention may include a first object 320, a second object 330 and a heat transfer adhesive material 350 which is placed between the first object 320 and the second object 330 so as to be in contact with the first object 320 and the second object 330. Here, the first object 320 and the second object 330 are the same as the case of the second embodiment, and thus description thereof will be omitted.

The heat transfer adhesive material 350 in accordance with the third embodiment of the present invention may include a resin 355 and at least one thermal conductive material 351. Since those materials are the same as those of the second embodiment, and thus description thereof will be omitted.

However, differently from the first or second embodiment, in the third embodiment, the thermal conductive material 351 may comprise a core member 352 and a shell (outer surface).

The core member 352 may be of a material having elasticity such as a polymer, but is not limited thereto and the shell or outer surface may be of a material such as Ag, Au, Al, Ni, Cu, Pb, etc., or a combination thereof.

In case where the thermal conductive material 351 is pressed by a pressure which is applied to the first object 320 and the second object 330, the thermal conductive material 351 can be pressed without destroying or rupturing the shape and outer surface of the thermal conductive material 351 thanks to the elasticity of the core member 352. By such pressure, the thermal conductive material 351 can be in surface contact with at least one of the first object 320 or the second object 330.

The remaining configuration and manufacturing method of the heat transfer structure 300 in accordance with the third embodiment of the present invention are the same as the case of the heat transfer structure 200 presented in the second embodiment, and thus description thereof will be omitted.

In the third embodiment in accordance with the present invention, the heat transfer structure 300 has the direct thermal path from the first object 320 to the second object 330, the plurality of thermal conductive material 351 dispersed in one layer are uniform in size and the plurality of thermal conductive material 351 form surface contact with at least one of the first object 320 and the second object 330. Therefore, it is possible to obtain a higher thermal conductivity than that of the conventional TIM material having a point contact.

FIG. 7 is a diagram illustrating an exemplary thermal conductivity of the heat transfer structure 300 in accordance with the third embodiment of the present invention, varying in accordance with the pressure applied to the first object 320 and the second object 330. As shown in FIG. 7, in the heat transfer structure 300 in accordance with the third embodiment of the present invention, the thermal conductivity is in the range from 2.55 to 4.27 W/mK, whereas, in the conventional TIM material including an alumina, the thermal conductivity is in the range from 0.534 to 1.78 W/mK. Accordingly, it can be seen that the thermal conductivity of the conventional TIM material is lower than that of the heat transfer structure 300 in accordance with the third embodiment of the present invention. Also, it can be seen that in the heat transfer structure 300 in accordance with the third embodiment of the present invention, the thermal conductivity increases with the increased of the pressure, whereas, in the conventional TIM material, the thermal conductivity is constant regardless of the increase of the pressure. Such increase of the thermal conductivity explains that the contact area between the thermal conductive material 351 and the first object 320 and the second object 330 increases as the applied pressure increase, thereby increasing the thermal conductivity.

While the present invention has been shown and described in detail with respect to the embodiments, it will be understood that it is merely an exemplary and the present invention is not limited thereto. Therefore, it will be understood by those skilled in the art that various changes and modifications may be made without departing from the scope of the invention as defined by claims and equivalents.

What is claimed is:

1. A heat transfer structure, comprising:
a first object;
a second object; and
a thermal transfer adhesive material which is placed between the first object and the second object so as to be in contact with at least one of the first object or the second object,
wherein the heat transfer adhesive material includes:
a resin; and
at least one thermal conductive material, and wherein the at least one thermal conductive material is distributed by being dispersed in the resin and forms surface contact with at least one of the first object or the second object.

2. The heat transfer structure of claim 1, wherein the at least one thermal conductive material is uniform in size.

3. The heat transfer structure of claim 1, wherein a thermal conductivity of the thermal conductive material is in the range of 1 to 5000 W/mK.

4. The heat transfer structure of claim 1, wherein the surface contact is formed by partially melting of outer surface of the thermal conductive material.

5. The heat transfer structure of claim 4, wherein a melting temperature of the thermal conductive material is lower than a thermal decomposing temperature of the resin.

6. The heat transfer structure of claim 4, wherein the melting temperature of the thermal conductive material is in the range of 20° C. to 450° C.

7. The heat transfer structure of claim 4, wherein the thermal conductive material is at least any one or combination of Sn, Ag, Bi, Pb, Cd, Zn, SnAg, SnBi, InSn, SnCu, SnPb and SnCuAg.

8. The heat transfer structure of claim 1, wherein the surface contact is formed by a pressure applied to the thermal conductive material.

9. The heat transfer structure of claim 8, wherein the thermal conductive material is comprised of a metal or a carbon containing material.

10. The heat transfer structure of claim 8, wherein the thermal conductive material includes a core member with elasticity placed inside thereof.

11. A method of manufacturing a heat transfer structure, comprising:
placing a heat transfer adhesive material between a first object and a second object, wherein the heat transfer adhesive material including a resin and at least one thermal conductive material which is distributed by being dispersed in the resin;
applying a pressure to the thermal conductive material so as for the thermal conductive material to be in contact with at least one of the first object or the second object;
forming surface contact, by partially melting of outer surface of the thermal conductive material, between the thermal conductive material and the at least one of the first object or the second object; and
curing the resin.

12. The method of claim 11, wherein a melting temperature of the thermal conductive material is lower than a thermal decomposing temperature of the resin.

13. The method of claim of 11, wherein the melting temperature of the thermal conductive material is in the range of 20° C. to 450° C.

14. The method of claim 11, wherein the thermal conductive material is at least any one or combination of Sn, Ag, Bi, Pb, Cd, Zn, SnAg, SnBi, InSn, SnCu, SnPb and SnCuAg.

15. A manufacturing method of a heat transfer structure, comprising:
placing a heat transfer adhesive material between a first object and a second object, wherein the heat transfer adhesive material including a resin and at least one thermal conductive material which is distributed by being dispersed in the resin;
applying a pressure to the first object and the second object so as to form surface contact between for the thermal conductive material and at least one of the first object or the second object; and
curing the resin.

16. The method of claim 15, wherein the thermal conductive material is comprised of a metal or a carbon containing material.

17. The method of claim 15, wherein the thermal conductive material includes a core member with elasticity placed inside thereof.

18. The method of claim 11, wherein the at least one thermal conductive material is uniform in size.

19. The method of claim 11, wherein a thermal conductivity of the thermal material is in the range of 1 to 5000 W/mK.

20. The method of claim 15, wherein the at least one thermal conductive material is uniform in size.
